(19) United States
(12) Patent Application Publication
(10) Pub. No.: US 2015/0214161 A1
(43) Pub. Date: Jul. 30, 2015

(54) SEMICONDUCTOR STRUCTURE

(71) Applicant: ALi Corporation, Hsinchu City (TW)

(72) Inventor: Ho-Wei CHANG, Hsinchu (TW)

(73) Assignee: ALi Corporation, Hsinchu City (TW)

(21) Appl. No.: 14/288,966

(22) Filed: May 28, 2014

(30) Foreign Application Priority Data
Jan. 28, 2014 (CN) 201410042543.X

(51) Int. Cl. H01L 23/552; H01L 23/00

(52) U.S. Cl. CPC H01L 23/552; H01L 24/49; H01L 2924/3025

(57) ABSTRACT

A semiconductor structure comprising a tray, a chip, a first grounding wire and a second grounding wire is provided. The tray has a first surface and a second surface, and there is a height difference existing between the first surface and the second surface. The chip is disposed on the first surface of the tray and has an active surface. The first grounding wire connects the active surface and the second surface. The second grounding wire connects the first surface and the second surface.

This application claims the benefit of People's Republic of China application Serial No. 201410042543.X, filed Jan. 28, 2014, the subject matter of which is incorporated herein by reference.

### BACKGROUND OF THE INVENTION

1. Field of the Invention

The invention relates in general to a semiconductor structure, and more particularly to a semiconductor structure having grounding wires.

2. Description of the Related Art

In response to the requirements for increasing speed and reducing size, semiconductor components become very complicated. When the benefits generated from speed increase and size reduction are significant, problems would occur to the characteristics of semiconductor components. Particularly, higher clock speed will generate more occurrences of transition between signal levels, so as to generate higher intensity of electromagnetic emission when the semiconductor components operate under high frequencies or short waves. Electromagnetic emission may radiate from a semiconductor component and its adjacent semiconductor components. If an adjacent semiconductor component has a high intensity of electromagnetic emission, the electromagnetic emission will negatively affect the operation of the semiconductor component.

Thus, how to decrease the influence of electromagnetic emission on the semiconductor components has become a prominent task for the industries.

### SUMMARY OF THE INVENTION

The invention is directed to a semiconductor package capable of decreasing the intensity of electromagnetic radiation.

According to one embodiment of the present invention, a semiconductor structure is provided. The semiconductor structure comprises a tray, a chip, a first grounding wire and a second grounding wire. The tray has a first surface and a second surface, and there is a height difference existing between the first surface and the second surface. The chip is disposed on the first surface of the tray and has an active surface. The first grounding wire connects the active surface and the second surface. The second grounding wire connects the first surface and the second surface.

The above and other aspects of the invention will become better understood with regard to the following detailed description of the preferred but non-limiting embodiment (s). The following description is made with reference to the accompanying drawings.

### BRIEF DESCRIPTION OF THE DRAWINGS

FIG. 1 is a cross-sectional view of a semiconductor package according to an embodiment of the invention.

FIG. 2 is a partial top view of FIG. 1.

FIG. 3 is another appearance diagram of a semiconductor package according to another embodiment of the invention.

FIG. 4 is a test simulation diagram of a semiconductor package according to an embodiment of the invention.

### DETAILED DESCRIPTION OF THE INVENTION

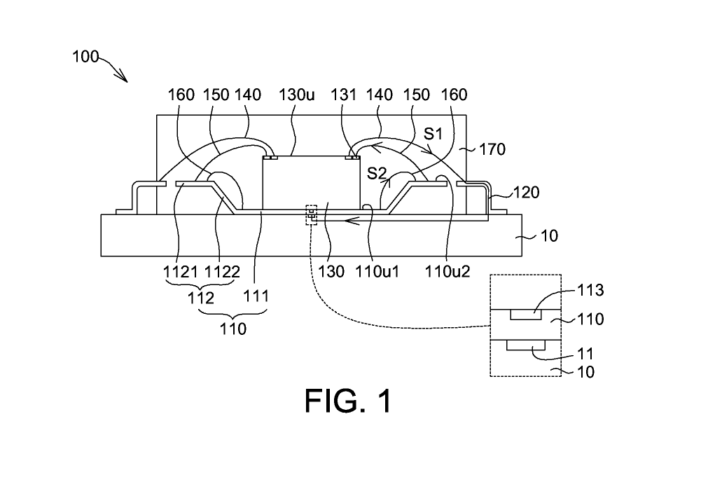

FIG. 1 is a cross-sectional view of a semiconductor package according to an embodiment of the invention. The semiconductor package 100 comprises a tray 110, a plurality of outer leads 120, a chip 130, a plurality of wires 140, at least a first grounding wire 150, at least a second grounding wire 160 and a package body 170.

The tray 110 has a first surface 110u1 and a second surface 110u2, and there is a height difference existing between the first surface 110u1 and the second surface 110u2. The second surface 110u2 is located at a position higher than the first surface 110u1 but lower than the active surface 130u of the chip 130.

The outer leads 120 are extended from the package body 170 and electrically connected to the circuit board 10. The wires 140 connect the outer leads 120 and the chip 130, such that the chip 130 is electrically connected to the circuit board 10 through the wires 140 and the outer leads 120. The outer leads 120 and the tray 110 are separated from each other to avoid the outer leads 120 and the tray 110 becoming electrically short-circuited.

The chip 130 is disposed on the first surface 110u1 of the tray 110 and comprises a plurality of pads 131 located on the active surface 130u. A current signal S1 outputted from the pads 131 of the chip 130 is provided to the circuit board 10 after passing through the wires 140 and the outer leads 120. Then, the current signal S1 is processed by the circuit board 10.

The first grounding wire 150 connects the active surface 130u and the second surface 110u2, and the second grounding wire 160 connects the first surface 110u1 and the second surface 110u2. After passing through the circuit board 10, the current signal S1, which sequentially passes through a grounding point 11 of the circuit board 10, the tray 110, returns to the active surface 130u of the chip 130 as a return current signal S2 which passes through the second grounding wire 160 and the first grounding wire 150. The grounding point 11 is such as a solder point formed on the circuit board 10.

The package body 170 encapsulates the tray 110, a part of the outer leads 120, the chip 130, the wires 140, the first grounding wire 150 and the second grounding wire 160 to protect these components from being damaged by the environment, for example, being oxidized.

As indicated in FIG. 1, the tray 110 comprises a chip carrying portion 111 and one or several bending plates 112. Let several bending plates 112 be taken for example. Each bending plate 112 comprises a wire carrying portion 1121 and a connection portion 1122, wherein the connection portion 1122 connects the chip carrying portion 111 and the wire carrying portion 1121. The first surface 110u1 is an upper surface of the chip carrying portion 111, and the second surface 110u2 is an upper surface of the wire carrying portion 1121. In the present embodiment, the wire carrying portion 1121 is extended outward from the connection portion 1122, such that the second surface 110u2 is extended outwards relative to the first surface 110u1. Besides, the chip carrying portion 111 and the connection portion 1122 form a recess, such as a bowl-shaped recess or a U-shaped recess, but the present embodiment of the invention is not limited thereto. The chip carrying portion 111 and the connection portion 1122 may also be connected slantwise or vertically. Furthermore, the connection between the chip carrying portion 111 and the connection portion 1122 may be a sharp connection or a smooth connection.

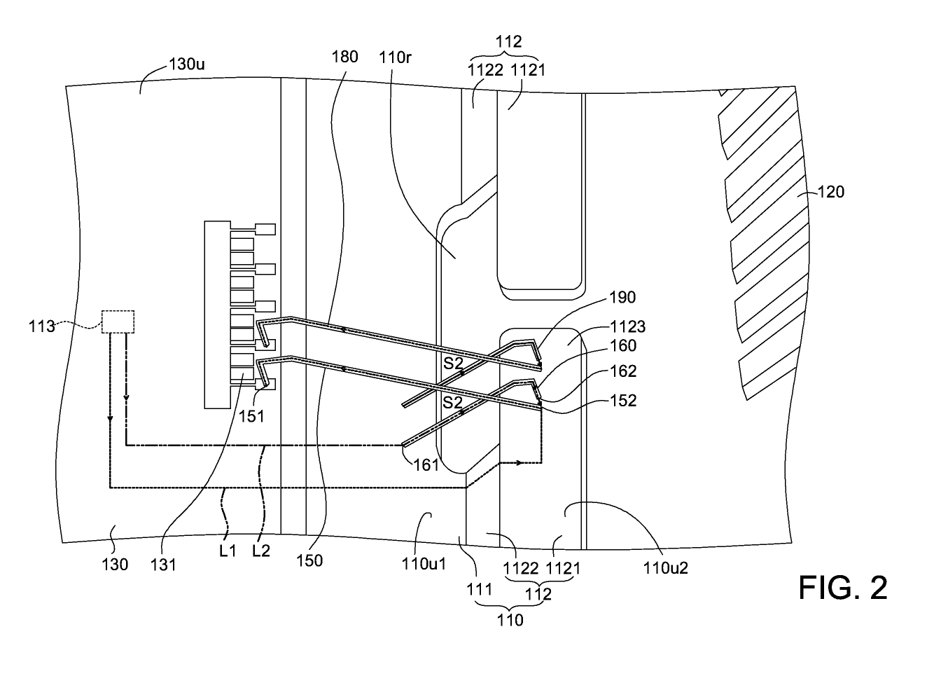

FIG. 2 is a partial top view of FIG. 1. To avoid the drawing becoming too complicated, wires 140 are not shown in FIG. 2. The first surface 110u1 of the tray 110 has a grounding point 113 corresponding to the grounding point 11 of the circuit board 10 (shown in FIG. 1). A first path length L1 is larger than a second path length L2. The first path length L1 starts from the grounding point 113, passes through the chip carrying portion 111, the connection portion 1122, the wire carrying portion 1121, and the first grounding wire 150 and reaches the chip 130. The second path length L2 starts from the grounding point 113, passes through the chip carrying portion 111, the second grounding wire 160, the wire carrying portion 1121, and the first grounding wire 150 and reaches the chip 130. Due to the design of the first grounding wire 150 and the second grounding wire 160 of the present embodiment, the return current signal S2 will return to the chip 130 via the second path length L2 which is shorter than the first path length L1, so that the intensity of electromagnetic radiation may be reduced.

As indicated in FIG. 2, the tray 110 further comprises at least a separation recess 110r which separates two adjacent bending plates 112. To avoid the drawing becoming too complicated, only one separation recess is illustrated in FIG. 2. The first grounding wire 150 has a first A end 151 and a first B end 152, which are connected to the active surface 130u and the second surface 110u2, respectively. The second grounding wire 160 has a second A end 161 and a second B end 162, which are connected to the first surface 110u1 and the second surface 110u2, respectively. In the present embodiment, the wire carrying portion 1121 is circumferentially extended from a lateral side of the connection portion 1122 to form a circumferential extending portion 1123. The first B end 152 of the first grounding wire 150 and the second B end 162 of the second grounding wire 160 are both soldered on the circumferential extending portion 1123. The first B end 152 and the second B end 162 are on the circumferential extending portion 1123 and close to each other. In the present embodiment, since the second A end 161 of the second grounding wire 160 is adjacent to the grounding point 113, the return current signal S2 returns to the chip 130 via the second grounding wire 160 nearby instead of bypassing the connection portion 1122 and the circumferential extending portion 1123, which are farther away.

In addition, since the second A end 161 of the second grounding wire 160 is located between the first A end 151 and the first B end 152 of the first grounding wire 150, a shorter second grounding wire 160 may be obtained, and the second path length L2 is shorter than the first path length L1.

As indicated in FIG. 2, the first grounding wire 150 is adjacent to the second grounding wire 160, such that the return current signal S2, which starts from the first surface 110u1, passes through the second grounding wire 160 and reaches the second surface 110u2, can return to the chip 130 via the first grounding wire 150 nearby, and the return path length can thus be reduced. If the distance between the first B end 152 of the first grounding wire 150 and the second B end 162 of the second grounding wire 160 is shorter, the return path length is shorter.

The semiconductor package 100 selectively comprises at least a third grounding wire 180 connecting the active surface 130u and the second surface 110u2. The first grounding wire 150, the second grounding wire 160 and the third grounding wire 180 are staggered on the second surface 110u2, and the second grounding wire 160 is located between the first grounding wire 150 and the third grounding wire 180.

The semiconductor package 100 selectively comprises at least a fourth grounding wire 190 connecting the first surface 110u1 and the second surface 110u2. The second grounding wire 160, the third grounding wire 180 and the fourth grounding wire 190 are staggered on the second surface 110u2, and the third grounding wire 180 is located between the second grounding wire 160 and the fourth grounding wire 190. The structures of the third grounding wire 180 and the fourth grounding wire 190 are similar to the structures of the first grounding wire 150 and the second grounding wire 160, respectively, and the similarities are not repeated here. The third grounding wire 180 is adjacent to the fourth grounding wire 190, such that the return current signal S2, which starts from the first surface 110u1, passes through the fourth grounding wire 190 and reaches the second surface 110u2, can return to the chip 130 via the third grounding wire 180 nearby, and the return path length can thus be reduced.

In another embodiment, the fourth grounding wire 190 can be omitted. Under such design, the return current signal S2, which starts from the first surface 110u1, passes through the second grounding wire 160 and reaches the second surface 110u2, can also return to the chip 130 via the third grounding wire 180. To be more specifically, for the same wire carrying portion 1121, as long as one grounding wire connects the wire carrying portion 1121 and the chip 130, the return current signal S2, which passes through the second grounding wire 160 and/or the fourth grounding wire 190, can return to the chip 130 via the same grounding wire.

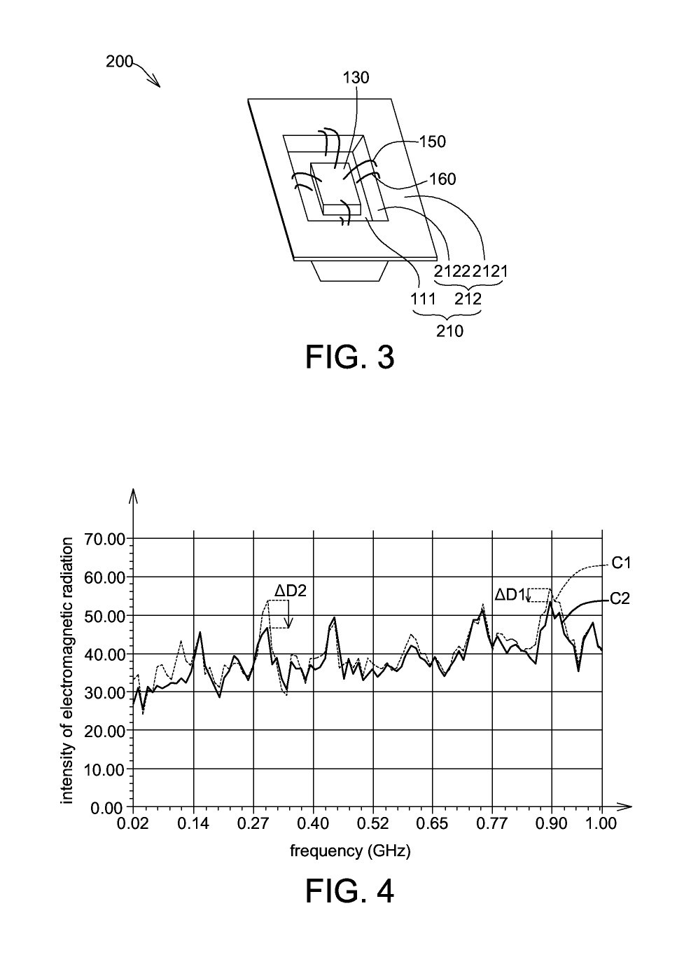

FIG. 3 is another appearance diagram of a semiconductor package according to another embodiment of the invention. The semiconductor package 200 comprises a tray 210, a plurality of outer leads 120 (not illustrated), a chip 130, a plurality of wires 140 (not illustrated), at least a first grounding wire 150, at least a second grounding wire 160 and a package body 170. The tray 210 comprises a chip carrying portion 111 and a plurality of bending plates 212. Each bending plate 212 comprises a wire carrying portion 2121 and a connection portion 2122. The connection portion 2121 is an intact sidewall. That is, the connection portion 2122 does not have any hollowed patterns.

FIG. 4 is a test simulation diagram of a semiconductor package according to an embodiment of the invention. Curve C1 represents the intensity of electromagnetic radiation of a semiconductor package having a first grounding wire 150 but not having a second grounding wire 160. Curve C2 represents the intensity of electromagnetic radiation of a semiconductor package 100 or 200 of the invention having a first grounding wire 150 and a second grounding wire 160. In comparison to the intensity of electromagnetic radiation of curve C1, the intensity of electromagnetic radiation of curve C2 obtained by a semiconductor package having a first grounding wire 150 and a second grounding wire 160 according to an embodiment of the invention is apparently smaller regardless of the frequency band being low or high. For example, the intensity of electromagnetic radiation under a high frequency band has a drop ΔD1 about 3 db, and has a drop ΔD2 under a low frequency band. It is apparent that ΔD2 is larger than ΔD1 which is about 3 db.

While the invention has been described by way of example and in terms of the preferred embodiment (s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A semiconductor structure, comprising:
a tray having a first surface and a second surface, wherein there is a height difference existing between the first surface and the second surface;
a chip disposed on the first surface of the tray and having an active surface;
a first grounding wire connecting the active surface and the second surface; and
a second grounding wire connecting the first surface and the second surface.

2. The semiconductor structure according to claim 1, further comprising:
a third grounding wire connecting the active surface and the second surface;
wherein, the first grounding wire, the second grounding wire and the third grounding wire are staggered on the second surface, and the second grounding wire is located between the first grounding wire and the third grounding wire.

3. The semiconductor structure according to claim 2, further comprising:
a fourth grounding wire connecting the first surface and the second surface;
wherein, the second grounding wire, the third grounding wire and the fourth grounding wire are staggered on the second surface, and the third grounding wire is located between the second grounding wire and the fourth grounding wire.

4. The semiconductor structure according to claim 1, the second surface is located at a height position between the active surface and the first surface.

5. The semiconductor structure according to claim 1, wherein the second surface is higher than the first surface and extended outward relative to the first surface.

6. The semiconductor structure according to claim 1, wherein the tray comprises a chip carrying portion and a bending plate, and the chip carrying portion and the bending plate form a recess.

7. The semiconductor structure according to claim 6, wherein the bending plate of the tray is an intact sidewall.

8. The semiconductor structure according to claim 1, wherein the tray comprises a chip carrying portion, a separation recess and two bending plates, the separation recess separates the two bending plates, and each bending plate comprises:
a wire carrying portion; and
a connection portion connecting the chip carrying portion and the wire carrying portion.

9. The semiconductor structure according to claim 8, wherein the first surface of the tray has a grounding point, and a first path length, which starts from the grounding point, passes through the chip carrying portion, the connection portion, the wire carrying portion, the first grounding wire and reaches the chip, is larger than a second path length, which starts from the grounding point, passes through the chip carrying portion, the second grounding wire, the wire carrying portion, the first grounding wire and reaches the chip.

10. The semiconductor structure according to claim 1, wherein a first A end and a first B end of the first grounding wire are connected to the active surface and the second surface respectively, a second A end and a second B end of the second grounding wire are connected to the first surface and the second surface respectively, and the second A end of the second grounding wire is located between the first A end and the first B end of the first grounding wire.

11. The semiconductor structure according to claim 1, further comprising:
a package body encapsulating the tray, the chip, the first grounding wire and the second grounding wire.

12. The semiconductor structure according to claim 11, further comprising:
an outer lead separated from the tray and extended to an exterior of the package body.
